(19) United States
(12) Patent Application Publication
(10) Pub. No.: US 2012/0025328 A1
(43) Pub. Date: Feb. 2, 2012

(54) MOSFET STRUCTURE AND METHOD FOR FABRICATING THE SAME

(76) Inventors: Zhijiong Luo, Poughkeepsie, NY (US); Huilong Zhu, Poughkeepsie, NY (US); Haizhou Yin, Poughkeepsie, NY (US)

(21) Appl. No.: 13/062,041

(22) PCT Filed: Sep. 27, 2010
(86) PCT No.: PCT/CN10/01496

§ 371 Date: Mar. 3, 2011

(30) Foreign Application Priority Data
Jul. 30, 2010 (CN) 201010242722.X

(51) Int. Cl. H01L 29/78; H01L 21/336

(52) U.S. Cl. 257/411; 438/591; 257/E29.255; 257/E21.409

(57) ABSTRACT

There are provided a MOSFET structure and a method for fabricating the same. The MOSFET structure comprises: a semiconductor substrate; a gate stack formed on the semiconductor substrate, including a high-k gate dielectric layer and a gate conductor layer formed sequentially on the semiconductor substrate; a first spacer which surrounds at least the high-k gate dielectric layer and comprises a La containing oxide; and a second spacer which surrounds the gate stack and the first spacer and is higher than the first spacer. Embodiments of the present invention are applicable to the fabrication of integrated circuits.

### FIELD OF INVENTION

The present invention generally relates to semiconductor devices and the fabrication thereof, and more particularly, to a MOSFET (Metal Oxide Semiconductor Field Effect Transistor) structure and a method for fabricating the same.

### DESCRIPTION OF PRIOR ART

With the development of the semiconductor technology, transistors are increasingly scaled down, resulting in improved speeds of devices and systems. In such a transistor with decreased sizes, the gate dielectric layer such as SiO₂ is becoming very thin. However, if the thickness of SiO₂ is less than a certain thickness, it will not achieve a good isolation. As a result, leakage currents from the gate to the active regions are likely to occur, which deteriorate the device performance.

Thus, instead of the conventional gate stack structure of SiO₂/poly-silicon, a gate stack structure of high-k material/metal is proposed. Here, so called “high-k material” refers to a material with a dielectric constant k greater than 3.9. For example, the high-k material may comprise HfO₂, HfSiO, HfSiON, HfTaO, HfTiO, HfZrO, Al₂O₃, or La₂O₃, etc. It is possible to significantly suppress the above described leakage currents by using the high-k material as the gate dielectric layer.

It has already been known that the introduction of a material such as La into the gate dielectric layer material will effectively lower the threshold voltage (Vt) of a transistor, which helps to improve the device performance. However, the effectiveness of lowering the threshold voltage Vt by the material such as La is affected by various factors. For example, in reference 1 (M. Inoue et al, “Impact of Area Scaling on Threshold Voltage Lowering in La-Containing High-k/Metal Gate NMOSFETs Fabricated on (100) and (110) Si”, 2009 Symposium on VLSI Technology Digest of Technical Papers, pp. 40-41), the effectiveness of La is studied, and it is found that there are a strong narrow width effect (that is, the narrower is the gate width, the less effective is La) and a corner effect (that is, round corners of the channel region affect the effectiveness of La).

As the channel is becoming narrower and narrower, the effectiveness of the gate dielectric layer is affected in the channel region. Therefore, it is necessary to take further measures to effectively achieve the lowering of the threshold voltage Vt.

### SUMMARY OF THE INVENTION

In view of the above problems, it is an object of the present invention to provide a Metal Oxide Semiconductor Field Effect Transistor (MOSFET) structure and a method for fabricating the same, whereby it is possible to reduce the variation of threshold voltage (Vt) across the channel length and channel width and thus to improve the device performance.

According to an aspect of the present invention, there is provided a Metal Oxide Semiconductor Field Effect Transistor (MOSFET), comprising: a semiconductor substrate; a gate stack formed on the semiconductor substrate, the gate stack including a high-k gate dielectric layer and a gate conductor layer, which are formed sequentially on the semiconductor substrate; a first spacer, which surrounds at least the high-k gate dielectric layer and comprises a La containing oxide; and a second spacer, which surrounds the gate stack and the first spacer and is higher than the first spacer.

Alternatively, the first spacer may be higher than the gate dielectric layer and lower than the gate stack. If such La containing oxide material covers all the gate stack, then a parasitic capacitance for the gate will be significantly increased. Therefore, preferably the first spacer is higher than the gate dielectric layer by no more than 10 nm.

Preferably, the high-k gate dielectric layer comprises any one or more selected from HfO₂, HfSiO, HfSiON, HfTaO, HfTiO, HfZrO, Al₂O₃, La₂O₃, ZrO₂, LaAlO and TiO₂.

Here, the La containing oxide comprises any one or more selected from La₂O₃, LaAlO, LaHfO and LaZrO.

Preferably, the first spacer has a thickness being smaller than or equal to 5 nm, and the second spacer may comprise an oxide.

There may also be a third spacer which surrounds the second spacer. That is, the second spacer is interposed between the first spacer and the third spacer. The third spacer may comprise an oxide, a nitride or a low-k material. The low-k material may comprise any one or more selected from SiO₂, SiOF, SiCOH, SiO and SiCO.

According to another aspect of the present invention, there is provided a method of fabricating a Metal Oxide Semiconductor Field Effect Transistor (MOSFET), comprising: providing a semiconductor substrate; forming a high-k gate dielectric layer and a gate conductor layer sequentially on the semiconductor substrate, and patterning the high-k gate dielectric layer and the gate conductor layer to form a gate stack; forming a first spacer, which surrounds at least the high-k gate dielectric layer and comprises a La containing oxide; and forming a second spacer, which surrounds the gate stack and the first spacer and is higher than the first spacer.

The step of forming the first spacer may comprise: depositing a first oxide layer which comprises the La containing oxide; etching the first oxide layer to form a first sacrificing spacer which surrounds the gate stack; and further etching the first sacrificing spacer to form the first spacer which surrounds at least the high-k gate dielectric layer.

The first oxide layer comprises a La containing oxide. The La containing oxide may comprises any one or more selected from La₂O₃, LaAlO, LaHfO and LaZrO.

In order to avoid an excessively large parasitic capacitance for the gate, after the further etching, the first spacer is higher than that of the gate dielectric layer by no more than 10 nm.

The step of forming the second spacer may comprise: depositing a second oxide layer; and etching the second oxide layer to form the second spacer which surrounds the gate stack and the first spacer.

Preferably, after forming the second spacer, the method further comprises: depositing a third oxide layer, a nitride layer, or a low-k material layer, and etching is the third oxide layer, the nitride layer, or the low-k material layer to form a third spacer surrounding the second spacer. The low-k material comprises any one or more selected from SiO₂, SiOF, SiCOH, SiO and SiCO.

According to an embodiment of the present invention, a first spacer formed of the La oxide is incorporated into the gate spacers. Since the La element diffuses into the gate dielectric layer, it is possible to effectively lower the threshold voltage Vt of the transistor. Further, the height of first spacer is relatively low, and thus it is possible to avoid the occurrence of an excessively large parasitic capacitance for the gate.

### BRIEF DESCRIPTION OF THE DRAWINGS

The above and other objects, features and advantages of the present invention will be more apparent by describing embodiments of the present invention in detail with reference to the attached drawings, wherein:

FIGS. 1-5 are sectional views schematically showing intermediate structures in a part of the steps of a process flow for fabricating a MOSFET according to an embodiment of the invention; and

FIG. 6 is a sectional view schematically showing a MOSFET structure according to another embodiment of the present invention.

### DETAILED DESCRIPTION OF PREFERRED EMBODIMENTS

Hereinafter, the present invention is described with reference to embodiments shown in the attached drawings. However, it is to be understood that those descriptions are only provided for illustrative purposes, rather than limiting the present invention. Further, in the following, descriptions of known structures and techniques are omitted so as not to obscure the concept of the present invention.

In the drawings, various sectional views of semiconductor devices according to embodiments of the present invention are shown. However, they are not drawn to scale, and some features may be enlarged while some features may be omitted for purposes of clarity. Shapes, sizes and relative positions of respective regions and layers shown in the drawings are only illustrative, and deviations may occur due to manufacture tolerances and technical limits. Those skilled in the art can also devise regions/layers of different shapes, sizes, and relative positions as needed.

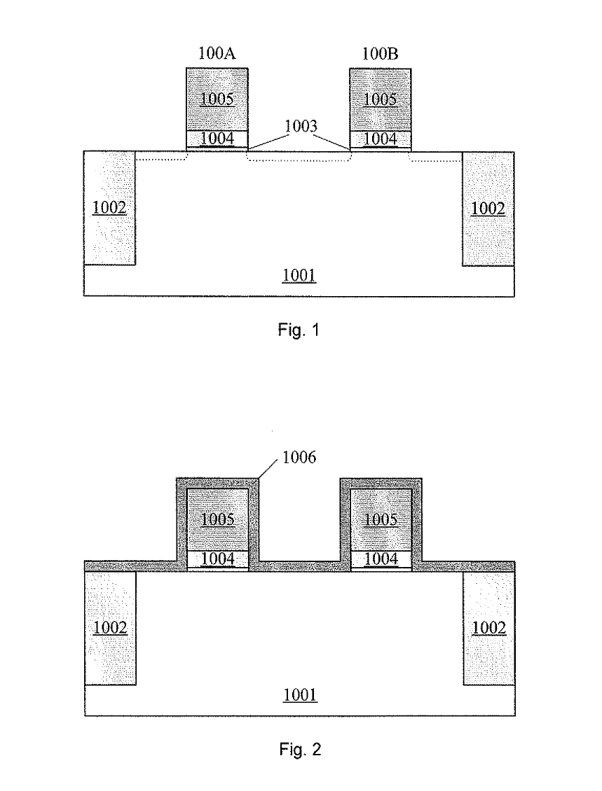

FIGS. 1-5 are sectional views schematically showing intermediate structures in a part of steps of a process flow for fabricating a Metal Oxide Semiconductor Field Effect Transistor (MOSFET) according to an embodiment of the invention.

Preferably, firstly as shown in FIG. 1, Shallow Trench Isolations (STIs) 1002 are formed in a semiconductor substrate 1001 to isolate individual device regions. For example, STIs 1002 may be made by etching shall trenches in the semiconductor substrate 1001 and then depositing SiO₂ or other dielectric materials.

Next, gate stacks 100A and 100B of the transistor structures are formed on the semiconductor substrate 1001. Here, two transistor structures are shown. However, it is to be understood by those skilled in the art that the present invention is not limited thereto. There may be only one transistor structure, or may be three or more transistor structures. Further, the position relationship between the two transistor structures is not limited to that shown in the drawings.

For example, each of the gate stacks 100A and 100B comprises a high-k material layer 1003 and a gate metal layer 1004, and preferably further comprises a poly-silicon layer 1005. The gate conductor layer referred to in the embodiments of the present invention comprises a stack structure of gate metal layer 1004/poly-silicon layer 1005. In other embodiments of the present invention, the gate metal layer may comprise a work function metal layer. Further, the gate conductor layer may comprise other structures. For example, a structure such as NiSi may be formed on the ploy-silicon to reduce the gate resistance. The gate stacks 100A and 100B may be formed in various manners. Specifically, for example, a gate dielectric layer of a high-k material, a gate metal layer, and an optional poly-silicon or amorphous silicon layer may be deposited sequentially on the substrate. For example, the high-k material may comprise any one or more materials selected from HfO₂, HfSiO, HfSiON, HfTaO, HfTiO, HfZrO, Al₂O₃, La₂O₃, ZrO₂, LaAlO and TiO₂, and have a thickness of 1-5 nm. The gate metal layer may, for example, comprise TaN, Ta₂C, HfN, HfC, TiC, TiN, MoN, MoC, TaTbN, TaErN, TaYbN, TaSiN, TaAlN, TiAlN, TaHfN, TiHfN, HfSiN, MoSiN, MoAlN, Mo, Ru, RuO₂, RuTaₓ, or NiTaₓ, etc., and have a thickness of 10-20 nm. The optional poly-silicon or amorphous silicon layer may, for example, have a thickness of 50-100 nm. Then, the deposited layers are patterned to form the gate stacks.

Subsequently, for example, an extension implantation may be carried out to form source/drain extensions (SDEs) at opposing sides of the respective gate stacks. The shallow junctions of the SDEs formed at the two ends of the respective channels will help to suppress short channel effects.

Next, as shown in FIG. 2, a La containing oxide layer 1006 is deposited on the semiconductor substrate 1001 including the gate stacks 100A and 100B, for example, to a thickness of about 3-5 nm. The material of this layer may, for example, comprise one or more selected from La₂O₃, LaAlO, LaHfO, and LaZrO. Here, the word “deposit” may comprise various methods for depositing materials, for example, including, but not limited to, CVD (Chemical Vapor Deposition), MBE (Molecule Beam Epitaxy), evaporation, and so on.

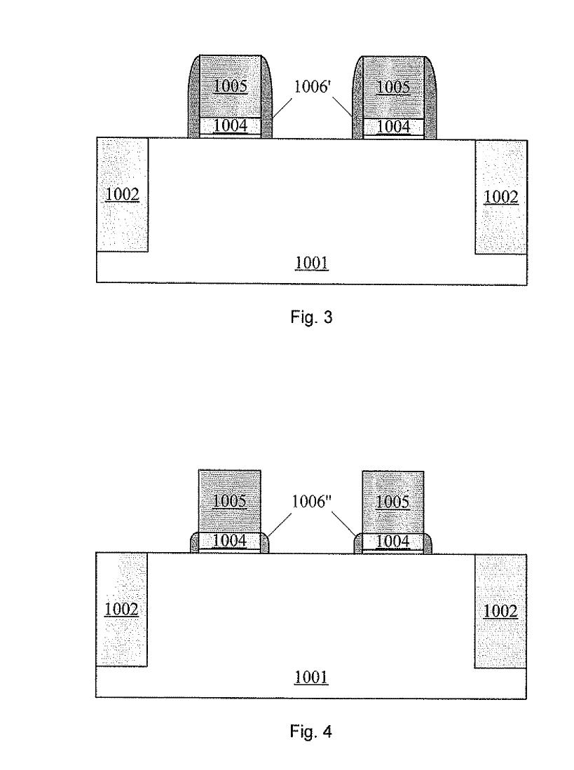

Subsequently, as shown in FIG. 3, the deposited La containing oxide layer 1006 is patterned by a conventional method for forming spacers, for example, by a dry etching such as RIE (Reactive Ion Etching), to form first sacrificing spacers 1006′. In order to obtain the first spacers desired in the embodiment of the present invention, the first sacrificing spacers 1006′ must be further etched by RIE or other etching processes, so that only the portions of the first sacrificing spacers surrounding the respective high-k material layers 1003 and the respective gate metal layers 1004 are remained, as shown in FIG. 4, to form the first spacers 1006″. However, the embodiments of the present invention are not limited thereto. For example, in the above steps, the etching may be further conducted so that the La containing oxide layer only remains to surround the outsides of the respective gate dielectric layer, namely, the resulting first spacers are almost the same high as the respective gate dielectric layers. Since the first spacer is formed of a high-k dielectric material, it is likely to cause an excessive large parasitic capacitance for the gate. Thus, the lower the first spacer is, the lower the parasitic capacitance for the gate is. However, the first spacer cannot be too low to completely cover the gate dielectric layer. According to the embodiments of the present invention, the first spacer may be higher than the gate dielectric layer but lower than the whole gate stack. More preferably, the first spacer 1006″ is higher than the gate dielectric layer 1003 by no more than 10 nm, so that it is possible not only to supply La element into the gate dielectric layer but also not to increase the parasitic capacitance for the gate.

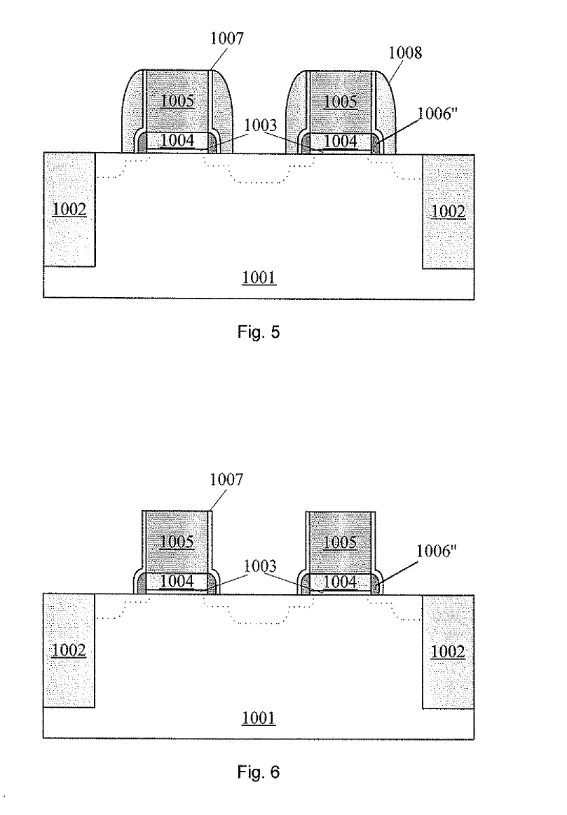

Next, other spacers, such as second spacers 1007 and third spacers 1008, are further fabricated. Here, as shown in FIG. 5, the second spacers and the third spacers cover the whole height of the gate stacks. Specifically, the second spacers 1007 may be made on the outsides of the first spacers 1006′ by depositing a further oxide layer such as SiO₂ on the semiconductor substrate 1001 having the first spacers formed thereon, and etching this oxide layer by a dry etching. Then, the third spacers 1008 may be made on the outsides of the second spacers 1007 by depositing a nitride layer such as Si₃N₄ on the outsides of the second spacers 1007, and etching the nitride layer. The methods for forming spacers are known in the art and details thereof are omitted here.

The third spacers 1008 are optional and not a must. If the third spacers 1008 are absent, the resulting structure will be that as shown in FIG. 6, which only comprises the first spacers and the second spacers.

Generally, the first spacer may have a thickness of 1-5 nm; the second spacer which comprise an oxide may have a thickness of 3-10 nm; and the third spacer which comprise an oxide, a nitride, or a low-k dielectric material, such as any one or more selected from SiO₂, SiOF, SiCOH, SiO and SiCO, may have a thickness of about 10-50 nm.

In the case where there are only the first and second spacers, the second spacers may have an appropriately increased thickness, for example, of 20-50 nm.

After the respective spacers are formed, a source/drain implantation is conducted by using the gate stacks 100A and 100B as a mask, so as to form source/drain regions, as shown by the dotted lines in FIG. 5. Since the formation of the source/drain regions is not directly relevant to the subject matter of the present invention, details thereof are omitted here.

Finally, the MOSFET structure according to an embodiment of the present invention is obtained, as shown in FIG. 5. Specifically, as shown in FIG. 5, the MOSFET comprises: a semiconductor substrate 1001; a gate stack formed on the semiconductor substrate 1001, including the gate dielectric layer 1003 and the gate conductor layer (in this embodiment, including the gate metal layer 1004 and the poly-silicon/amorphous silicon layer 1005); and spacers including a first spacer 1006″ surrounding at least the outsides of the gate dielectric layer 1003, a second spacer 1007 surrounding the gate stack and the first spacer 1006″, and an optional third spacer 1008 surrounding the second spacer.

In the embodiment shown in FIG. 4, the first spacer 1006″ is formed to surround the outsides of the gate dielectric layer 1003 and the gate metal layer 1004. However, according to the embodiments of the present invention, the first spacer 1006″ may be higher than or equal to the gate dielectric layers 1003, but lower than the second spacer, in other words, lower than the whole gate stack. More preferably, the first spacer 1006″ is higher than the gate dielectric layer 1003 by no more than 10 nm. In such an arrangement, La element in the first spacer can diffuse into the gate dielectric layer, facilitating the adjustment for Vt of the device, and the first spacers are relatively low so as not to significantly increase the parasitic capacitance for the gate.

In the embodiment shown in FIG. 5, the gate conductor layer is formed of a metal/poly-silicon stack. According to other embodiments of the present invention, the gate conductor layer may comprise other kinds of stacks, for which reference may be made to the existing art.

Here, the gate dielectric layer 1003 may comprise any one or more selected from HfO₂, HfSiO, HfSiON, HfTaO, HfTiO, HfZrO, Al₂O₃, La₂O₃, ZrO_{2:} LaAlO, and TiO₂, and has a thickness of, for example, 1-5 nm. The first spacer 1006″ preferably has a thickness not greater than 5 nm, and may be formed of a La containing oxide, such as any one or more selected from La₂O₃, LaAlO, LaHfO, and LaZrO. The second spacer has a thickness of about 3-10 nm, and may be formed of an oxide, such as any one or more selected from SiO₂, SiOF, SiCOH, SiO, and SiCO. The third spacer has a thickness of about 10-50 nm, and may comprise a nitride, an oxide, or a low-k dielectric material, such as any one or more selected from Si₃N₄, SiO₂, SiOF, SiCOH, SiO, and SiCO.

The MOSFET according to another embodiment of the present invention is shown in FIG. 6, which differs from that shown in FIG. 5 in that there are only the first spacers 1006″ and the second spacers 1007″ surrounding the respective gate stacks.

For a MOSFET having a high-k gate dielectric layer, the effectiveness of the gate dielectric layer, especially at edges of the channel, is more likely to be affected as the channel is becoming narrower. According to embodiments of the present invention, the first spacer 1006″ of La containing oxide are formed on the outsides of the gate stack, and thus a portion of La element can diffuse into the gate dielectric layer, which will effectively lower the threshold voltage Vt of the transistor and thus improve the device performance. Preferably, La₂O₃ may be introduced into the gate dielectric layer 1003 so as to lower the threshold voltage (Vt) of the finally completed transistor structure. Further, the first spacer is equal to or higher than the gate dielectric layer, but is lower than the whole gate stack. Therefore, it is possible to avoid a significant increasing of the parasitic capacitance for the gate.

In the above description, details of pattering and etching of the respective layers are not provided. It is to be understood by those skilled in the art that various means in the existing art may be utilized to form layers and regions having desired shapes. Further, to achieve the same structure, those skilled in the art may devise methods not completely the same as those described above.

The present invention is described above with reference to its embodiments. However, the embodiments are provided only for illustrative purposes, rather than limiting the present invention. The scope of the invention is defined by the attached claims as well as equivalents thereof. Those skilled in the art can make various alternations and modifications without departing from the scope of the invention, and these various alternations and modifications all fall into the scope of the invention.

1. A Metal Oxide Semiconductor Field Effect Transistor, comprising:
a semiconductor substrate;
a gate stack formed on the semiconductor substrate, the gate stack including a high-k gate dielectric layer and a gate conductor layer, which are formed sequentially on the semiconductor substrate;
a first spacer, which surrounds the bottom portion of the gate stack and comprises a La containing oxide; and
a second spacer, which surrounds the gate stack and the first spacer and is higher than the first spacer.

2. The transistor according to claim 1, wherein the first spacer is higher than the gate dielectric layer and lower than the gate stack.

3. The transistor according to claim 2, wherein the first spacer is higher than the gate dielectric layer by no more than 10 nm.

4. The transistor according claim 1, wherein the high-k gate dielectric layer comprises any one or more selected from HfO₂, HfSiO, HfSiON, HfTaO, HfTiO, HfZrO, Al₂O₃, La₂O₃, ZrO₂, LaAlO, and TiO₂.

5. The transistor according to claim 1, wherein the La containing oxide comprises any one or more selected from La₂O₃, LaAlO, LaHfO and LaZrO.

6. The transistor according to claim 1, wherein the first spacer has a thickness being smaller than or equal to 5 nm.

7. The transistor according to claim 1, wherein the second spacer comprises an oxide.

8. The transistor according to claim 1, further comprising a third spacer which surrounds the second spacer.

9. The transistor according to claim 8, wherein the third spacer comprises an oxide, a nitride, or a low-k material.

10. The transistor according to claim 9, where the low-k material comprises any one or more selected from SiO₂, SiOF, SiCOH, SiO, and SiCO.

11. A method for fabricating a Metal Oxide Semiconductor Field Effect Transistor, comprising:
providing a semiconductor substrate;
forming a high-k gate dielectric layer and a gate conductor layer sequentially on the semiconductor substrate, and patterning the high-k gate dielectric layer and the gate conductor layer to form a gate stack;
forming a first spacer, which surrounds the bottom portion of the gate stack and comprises a La containing oxide; and
forming a second spacer, which surrounds the gate stack and the first spacer and is higher than the first spacer.

12. The method according to claim 11, wherein the step of forming the first spacer comprises:
depositing a first oxide layer which comprises the La containing oxide;
etching the first oxide layer to form a first sacrificing spacer which surrounds the gate stack; and
further etching the first sacrificing spacer to form the first spacer which surrounds at least the high-k gate dielectric layer.

13. The method according to claim 12, wherein after the further etching, the first spacer is higher than the gate dielectric layer by no more than 10 nm.

14. The method according to claim 12, wherein the La containing oxide comprises any one or more selected from La₂O₃, LaAlO, LaHfO, and LaZrO.

15. The method according to claim 11, wherein the step of forming the second spacer comprises:
depositing a second oxide layer; and
etching the second oxide layer to form the second spacer which surrounds the gate stack and the first spacer.

16. The method according to claim 11, wherein after forming the second spacer, the method further comprises:
depositing a third oxide layer, a nitride layer, or a low-k material layer, and etching the third oxide layer, the nitride layer, or the low-k material layer to form a third spacer surrounding the second spacer.

17. The method according to claim 16, wherein the low-k material comprises any one or more selected from SiO₂, SiOF, SiCOH, SiO, and SiCO.
